(19) United States
(12) Patent Application Publication
(10) Pub. No.: US 2026/0341345 A1
(43) Pub. Date: Oct. 29, 2026

(54) Replica Write Driver Circuitry and Methods

(71) Applicant: Arm Limited, Cambridge (GB)

(72) Inventors: Rajiv Kumar Sisodia, Bangalore (IN); Disha Singh, Bangalore (IN); Prashantkumar Jayantilal Vaghasia, Austin, TX (US); Vishal Vinay Thakre, Austin, TX (US); Jaspreet Singh, Bangalore (IN); Sumant Kumar Thapliyal, Bangalore (IN)

(21) Appl. No.: 19/192,238

(22) Filed: Apr. 28, 2025

(51) Int. Cl. G11C 11/419

(52) U.S. Cl. CPC G11C 11/419

(57) ABSTRACT

A replica write driver circuit for bitline write assist includes a pull-down stack and control logic. The pull-down stack includes a first portion configured to receive a first voltage domain signal, and a second portion configured to receive a second voltage domain signal (different from the first voltage domain signal. The control logic is coupled to the pull-down stack, and is configured to dynamically select between the first and second voltage domain signals based on a voltage transition occurring last in time among the first and second voltage domain signals.

### I. FIELD

The present disclosure is generally related to replica write driver circuitry and methods.

### II. DESCRIPTION OF RELATED ART

In modern System-on-Chip (SoC) designs, Static Random-Access Memory (SRAM) plays a significant role, particularly in applications demanding low power consumption. SRAM memory cells often operate using two distinct voltage domains: a core voltage (VDDCE) specific to memory bitcells, and a peripheral voltage (VDDPE), that is shared with peripheral logic components of the memory and other logic outside the memory. A key design challenge arises as system-level power reduction techniques push operating voltages to increasingly lower levels.

Particularly, dynamic voltage fluctuations across VDDPE and VDDCE domains—such as scenarios where the peripheral voltage significantly overshoots the core voltage (e.g., VDDPE>>VDDCE)—can cause timing mismatches in SRAM memory circuits. In these cases, the negative bitline assist, critical for robust write operations in high-density SRAM bitcells, tends to arrive prematurely. Early arrival of the assist signal relative to the bitline discharge can lead to insufficient write margins; thereby causing write failures. Current static assist circuitry lacks adaptability to dynamically fluctuating voltage domains, exacerbating timing mismatches and memory unreliability. Therefore, there is a pressing need in the art for adaptive circuitry capable of dynamically compensating for fluctuations between voltage domains to maintain reliable and robust SRAM write operations across varying operational conditions.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is an example diagram in accordance with various implementations described herein.

FIG. 2 is an example diagram in accordance with various implementations described herein.

FIG. 3 is an example diagram in accordance with various implementations described herein.

FIG. 4 is an example diagram in accordance with various implementations described herein.

FIG. 5 is an example diagram in accordance with various implementations described herein.

FIG. 6 is an operational method in accordance with various implementations described herein.

FIG. 7 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a replica write driver circuit for bitline write assist. The circuit including a pull-down stack and control logic. The pull-down stack includes a first portion configured to receive a first voltage domain signal (e.g., VDDPE), and a second portion configured to receive a second voltage domain signal (e.g., VDDCE) different from the first voltage domain signal. The control logic is coupled to the pull-down stack, and is configured to dynamically select between the first and second voltage domain signals based on a voltage transition occurring last in time among the first and second voltage domain signals.

In another implementation, the present disclosure describes a method for bitline write assist. The method includes: 1) receiving a first voltage domain signal from a first voltage domain (e.g., VDDPE) and a second voltage domain signal from a first voltage domain (e.g., VDDPE) at respective portions of a pull-down transistor stack within control circuitry; 2) dynamically selecting between the first and second voltage domain signal based on a voltage transition occurring last in time among the first and second voltage domain signals; and 3) generating an assist signal based on the voltage transition of the selected voltage domain signal.

In another implementation, the present disclosure describes a circuit for bitline write assist. The circuit includes a first and second replica write driver circuits. The first replica write driver circuit is powered by a first voltage domain and includes a first logic gate powered by the first voltage domain and a first replica driver powered by a second voltage domain different from the first voltage domain. The second replica write driver circuit is powered by the second voltage domain and includes a second logic gate powered by the second voltage domain and a second replica driver powered by the first voltage domain. In addition, each of the first and second replica write driver circuits can generate a respective assist signal. Also, output logic is configured to receive the respective assist signals from the first and second replica write driver circuits and generate an assist enable output signal based on a voltage transition occurring last in time among voltage transitions from the first and second voltage domains.

To address above-described challenges, inventive aspects of the present invention introduce adaptive circuitry for negative bitline assist operations in SRAM memories, capable of dynamically adapting to voltage fluctuations between VDDPE and VDDCE domains (e.g., used interchangeably with VDDP and VDDC herein).

In certain implementations, inventive schemes and techniques broadly include adaptive replica write driver circuitry capable of receiving inputs from two separate voltage domains-VDDPE and VDDCE. For instance, such an adaptive replica circuitry ensures precise timing control of assist signals by responding to the voltage domain experiencing the “worst-case” (e.g., slowest) transition. Advantageously, the adaptive circuitry dynamically compensates for voltage fluctuations, ensuring that assist signals always trigger at the optimal time relative to the actual bitline discharge.

In some cases, inventive designs include the incorporation of adaptive bleeder circuitry (e.g., an adaptive bleeder device) within the adaptive replica write driver. Unlike conventional static bleeder circuits, in certain aspects, the inventive adaptive bleeder circuit includes transistors coupled across separate voltage domains, dynamically activating only during significant voltage domain differences. Specifically, when one voltage domain substantially exceeds the other (e.g., VDDPE significantly higher than VDDCE, or vice versa), the adaptive bleeder device introduces controlled leakage current. Advantageously, doing so, adaptively slows down the bitline discharge precisely when needed, extending the operational range and significantly enhancing memory write robustness.

Moreover, the inventive schemes and techniques further includes adaptive load balancing for signals originating from separate voltage domains (e.g., VDDPE and VDDCE). By optimizing and matching loads, the transitions of these signals remain synchronized (e.g., closely matched), contributing further to stable and robust write operations across a broad voltage spectrum. These combined adaptive features significantly improve the reliability, robustness, and flexibility of write assist functionality in SRAM designs, enabling robust memory operations even under dynamic and unpredictable voltage domain fluctuations inherent in modern SOC architectures.

Certain definitions have been provided herein for reference. A memory macro (e.g., memory macro unit, butterfly architecture) refers to a symmetric and interleaved arrangement of memory components, including bitcell arrays, word-line drivers, and input-output (I/O) circuitries, within a memory macro. This architecture optimizes signal propagation, reduces area overhead, and enhances power distribution by leveraging balanced and mirrored layouts, commonly used in high-performance memory systems such as SRAM. A memory subarray in a memory macro is a smaller, organized section of the overall memory array that comprises a subset of bitcells, word lines, and bit lines, along with associated peripheral circuitry. Subarrays are used to partition the memory for efficient access, reduced latency, and optimized signal distribution, enabling scalable and high-performance memory architectures.

Input/Output (I/O) (e.g., I/O circuitry) in a memory macro refers to circuitry that facilitates data transfer between the memory sub-array and external components, where each I/O circuitry, for example, corresponds to a subset of eight bitcell columns (pitch-wide) of the sub-array, managing read and write operations efficiently. Replica write driver circuitry describes circuitry that is structurally and functionally designed to replicate (e.g., mimic) the behavior of an actual write driver circuit used in the memory array, but does not itself directly drive the memory bitlines. In other words: a write driver circuit directly controls actual bitlines during write operations in the SRAM memory array. A replica write driver circuit, by contrast, simulates or “replicates” the electrical characteristics and behaviors (such as voltage transitions and timing delays) of an actual write driver circuit but does not drive the bitlines directly. Instead, it is used as a sensing or control element to accurately time assist signals, ensuring these assist signals arrive at the correct moment relative to the actual bitline discharge events. This distinction is critical because the adaptive timing control provided in inventive aspects rely on accurately replicating (hence, the term “replica”) the characteristics and timing of the real bitline behavior under varying voltage conditions. The “replica” aspect emphasizes that the circuitry's purpose is to precisely track and emulate actual bitline behavior, allowing the assist signal to be accurately timed and thereby improving memory robustness and reliability.

Negative bitline assist signal (WAEN) refers to a control signal specifically configured to facilitate robust write operations in SRAM by ensuring proper discharge timing. “Slower” voltage transition indicates the voltage domain signal transitioning from logic high to logic low at a slower rate compared to another signal from a different voltage domain. Bleeder circuitry is a transistor-based structure configured to selectively introduce controlled leakage current, causing an intentional delay in signal transitions when voltage domain differences exceed a predetermined threshold. Pull-down stack is a transistor stack arrangement configured to discharge the dummy bitline (DBL) signal and highlight its structural arrangement comprising transistor elements coupled to distinct voltage domains.

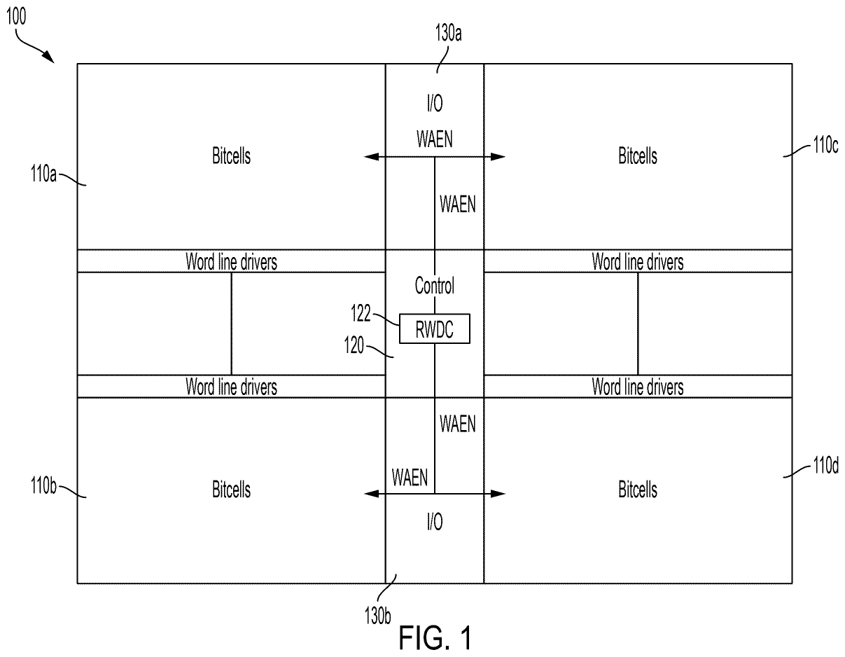

Referring to FIG. 1, a diagram of a circuit 100 according to example implementations is shown. In certain implementations, the circuit 100 may be a memory macro (e.g., memory macro unit, “butterfly” architecture) having at least: one or more bitcell arrays 110 (e.g., a memory array with bitcells), a control block 120, and I/O circuitry 130 (e.g., 130a, 130b). In certain aspects, the control block 120 includes replica write driver circuitry (RWDC) 122 (i.e., adaptive replica write driver circuitry) that generates a negative bitline assist enable signal (WAEN). The WAEN signal is transmitted first to the column circuitry within I/O blocks 130, and subsequently to the bitcell arrays 110a-d. Advantageously, this signal routing ensures proper timing and robustness of bitline discharge, facilitating reliable write operations.

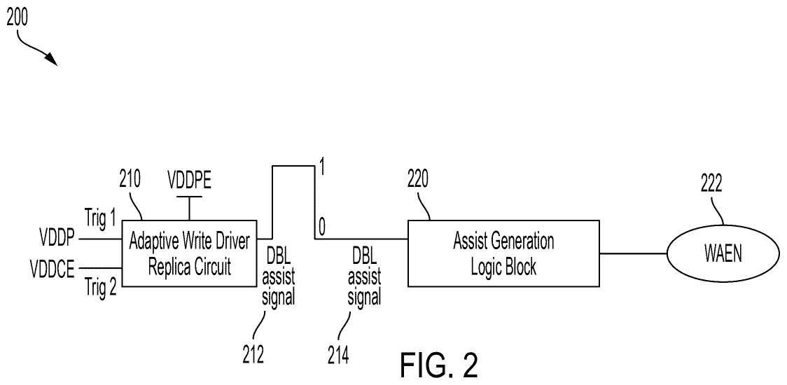

In certain implementations, the control block 120 is configured to provide a negative bitline assist signa (WAEN) during write operations. In some cases, as explained in greater detail with reference to FIG. 2, the adaptive replica write driver circuitry 122 receives inputs from two separate voltage domains, dynamically selects a “worst-case” voltage transition, and adaptively adjusts a timing of the negative bitline assist signal (WAEN) in response to voltage fluctuations.

Referring to FIG. 2, a flow diagram 200 according to example implementations is shown. As shown, FIG. 2 illustrates a simplified operational flow diagram 200 depicting a dual-domain negative bitline adaptive write driver replica circuit 210 (e.g., corresponding to RWDC 122 in FIG. 1). Specifically, FIG. 2 shows an adaptive write driver replica circuit 210 configured to receive two trigger signals: a first trigger signal (e.g., Trig 1) corresponding to a first voltage domain (VDDP), and a second trigger signal (e.g., Trig 2) corresponding to a second voltage domain (VDDCE). The adaptive write driver replica circuit 210 is further coupled to and powered by the first voltage domain (VDDPE).

In operation, the adaptive write driver replica circuit 210 receives the first and second trigger signals (Trig 1, Trig 2) and, based on these inputs (e.g., which of the first and second voltage domains exhibits the slower voltage transition), generates a dummy bitline assist signal 212 (e.g., DBL assist signal). For example, the dummy bitline assist signal 212 is configured to transition from a logic low (“0”) to a logic high (“1”), and subsequently, as dummy bitline assist signal 214, from logic high (“1”) to logic low (“0”), based on voltage transitions of the input trigger signals. Next, this DBL assist signal 212 then serves as an input to an assist generation logic block 220. Subsequently, the assist generation logic block 220 generates a negative bitline assist enable signal (WAEN) 222 based on the received DBL assist signal 214.

Moreover, in certain aspects, the negative bitline assist enable signal WAEN 222 is transmitted from the assist generation logic block 220 to column-side circuitry (not shown in FIG. 2), which typically includes elements such as column multiplexers, decoders, and local input/output circuitry within a memory architecture, such as an SRAM butterfly architecture (e.g., as shown in FIG. 1). In various implementations, the adaptive write driver replica circuit 210 and the assist generation logic block 220 can typically be positioned within a control block (e.g., control block 120) of a memory macro (e.g., circuit 100). Correspondingly, the WAEN signal 222 produced by the control block can be routed through the column-side circuitry to bitcell arrays (e.g., bitcell array 110) to enable or assist write operations, ensuring robust and properly timed bitline discharge during memory write cycles.

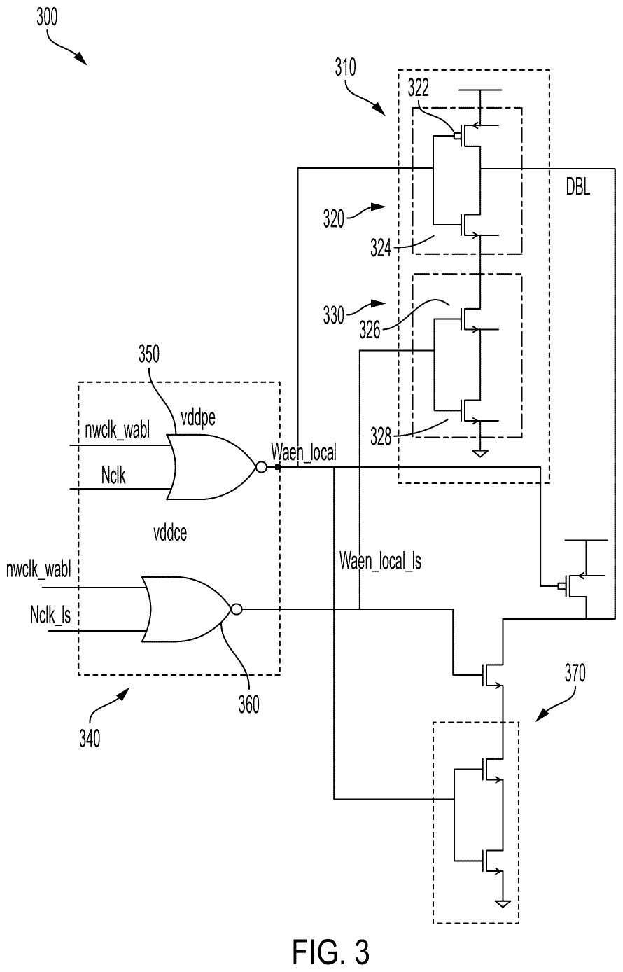

Referring to FIG. 3, a diagram of a circuit 300 according to example implementations is shown. As illustrated, the circuit 300 includes an example adaptive write driver replica circuitry for bitline write assist. In certain aspects, the circuit 300 includes a pull-down transistor stack 310 configured to control the timing of a negative bitline assist signal (DBL). The pull-down stack 310 comprises two distinct portions: a first portion 320 and a second portion 330. For instance, the first portion 320 of the pull-down stack includes a first PMOS transistor 322 and a first NMOS transistor 324. Gates of these transistors in the first portion 320 receive a first voltage domain signal (e.g., Waen_local), derived from a first voltage domain VDDPE. In addition, the second portion 330 of the pull-down stack 310 includes second and third NMOS transistors 326, 328. Gates of the second and third NMOS transistors 326, 328 receive a second voltage domain signal (e.g., Waen_local_ls), originating from a second voltage domain (VDDCE) that differs from the first voltage domain.

In such aspects, the circuit 300 further includes control logic 340 include first and second logic gates 350, 360 (e.g., first and second NOR gates). Specifically, the first logic gate 350 is powered by the first voltage domain (VDDPE) and receives a clock signal (e.g., nclk) and a trigger clock signal (e.g., nwclk_wabl). Similarly, the second logic gate 360 is powered by the second voltage domain (VDDCE) and receives the clock signal (e.g., nclk_ls) and trigger clock signal (e.g., nwclk_wabl). In certain implementations, the control logic 340 formed by the NOR gates 340, 350 selects between the first and second voltage domain signals based on a voltage transition occurring “second in time” between the respective voltage domain signals (e.g., where the control logic is configured to dynamically select (e.g., determine) from the first and second voltage domain signals having a slower (e.g., a “worst-case” delayed) voltage transition. Thus, the selected voltage domain signal generates an assist signal (DBL), that subsequently induces generation of the negative bitline assist enable signal (WAEN), thereby ensuring proper timing of bitline discharge during memory write operations.

In certain implementations, load balancing circuitry 370 along with circuit portion 330 are included within the circuit 300 to match or synchronize the timing transitions of the first and second voltage domain signals. This load balancing is typically achieved by balancing capacitive loads associated with signals from the respective voltage domains, ensuring synchronized transitions and optimized timing alignment of the negative bitline assist signal generation.

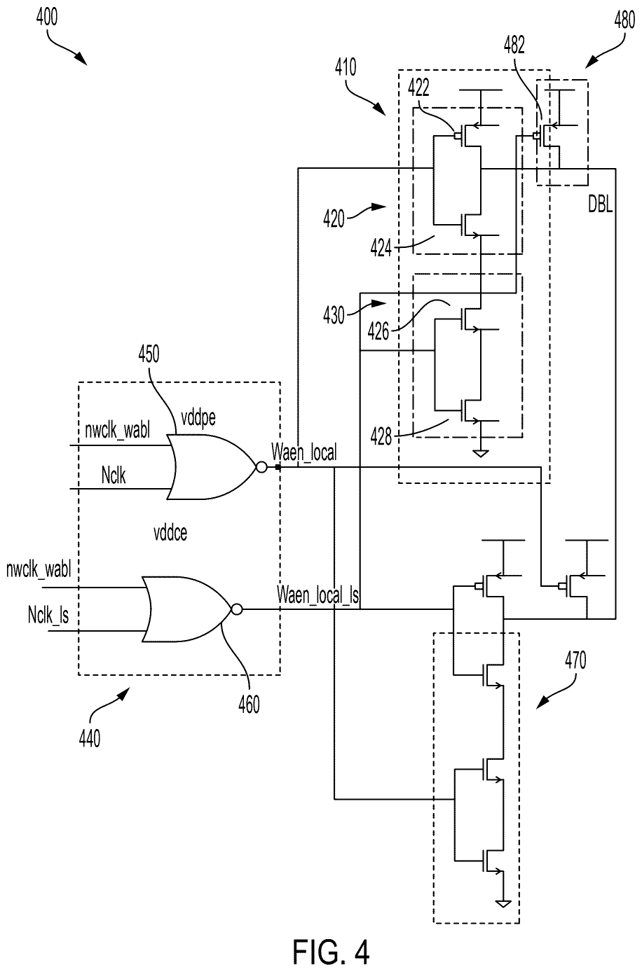

Referring to FIG. 4, a diagram of a circuit 400 according to example implementations is shown. As illustrates, the circuit 400 depicts an adaptive write driver replica circuitry for bitline write assist, similar to circuit 300 described above with reference to FIG. 3, but additionally includes explicit bleeder circuitry for controlled delay adjustment.

As shown, the circuit 400 includes a pull-down transistor stack 410 configured to control the timing of a negative bitline assist signal (DBL). The pull-down stack 410 includes two distinct portions: a first portion 420 and a second portion 430. Specifically, the first portion 420 includes a first PMOS transistor 422 and a first NMOS transistor 424. Gates of these transistors within the first portion 420 receive a first voltage domain signal (e.g., Waen_local) from a first voltage domain (VDDPE). Further, the second portion 430 of the pull-down stack 410 includes second and third NMOS transistors 426, 428, with gates configured to receive a second voltage domain signal (e.g., Waen_local_ls) from a second voltage domain (VDDCE), distinct from the first voltage domain.

The circuit 400 further comprises control logic 440 including first and second logic gates 450, 460 (e.g., first and second NOR gates). Specifically, the first logic gate 450 is powered by the first voltage domain (VDDPE) and receives a clock signal (e.g., nclk) and a trigger clock signal (e.g., nwclk_wabl). Similarly, the second logic gate 460 is powered by the second voltage domain (VDDCE) and receives a corresponding clock signal (e.g., nclk_ls) and trigger clock signal (e.g., nwclk_wabl). The control logic 440 selects between the first and second voltage domain signals based on a voltage transition occurring “last in time” between the respective signals, thus dynamically selecting the voltage domain signal having a slower or worst-case delayed transition. The selected voltage domain signal generates an assist signal (DBL) that subsequently induces generation of the negative bitline assist enable signal (WAEN), thereby ensuring proper timing of bitline discharge during memory write operations.

In certain implementations, load balancing circuitry 470 along with circuit portion 440 are included within the circuit 400 to match or synchronize timing transitions of the first and second voltage domain signals. Load balancing is typically achieved by balancing capacitive loads associated with signals from respective voltage domains, ensuring synchronized transitions and optimized timing alignment of the negative bitline assist signal generation.

Additionally, in contrast to the circuit 300, the circuit 400 explicitly incorporates bleeder circuitry 480 coupled to the pull-down stack 410. The bleeder circuitry 480 includes a PMOS transistor 482 having a gate terminal configured to receive one of the first or second voltage domain signals. This bleeder PMOS transistor 482 introduces a controlled leakage current, thereby extending or providing a controlled delay to the negative bitline assist signal (e.g., DBL), particularly when a voltage difference between the first and second voltage domain signals exceeds a predetermined threshold (e.g., greater than 200 mV). The controlled delay provided by the bleeder circuitry 480 ensures robust and precisely timed operation, even under voltage fluctuation conditions.

Moreover, as demonstrated by simulation results, the adaptive write driver replica circuitry described herein ensures precise timing alignment of the negative bitline assist enable signal (WAEN). In particular, simulation waveforms illustrate that the dummy bitline assist (DBL) signal reliably tracks and transitions according to the slower or “worst-case” voltage domain signal, whether originating from the first voltage domain (VDDPE) or second voltage domain (VDDCE). The circuitry thus ensures robust operation by aligning the assist signal timing with the actual bitline discharge event under various voltage domain conditions.

In addition, simulation comparisons confirm improved operational robustness even under significant voltage domain disparities. For instance, under conditions where the first voltage domain (VDDPE) is substantially higher (e.g., VDDPE=0.95 V) than the second voltage domain (VDDCE=0.675 V), the circuitry's dual-voltage-domain approach ensures the dummy bitline assist (DBL) signal discharge accurately tracks the delayed or worst-case voltage domain transition. This dual-domain configuration guarantees precise alignment between the negative bitline assist enable signal (WAEN) and associated control signals (e.g., CAP_CTRL), thereby ensuring robust and reliable memory write operations even when large voltage differences between domains occur.

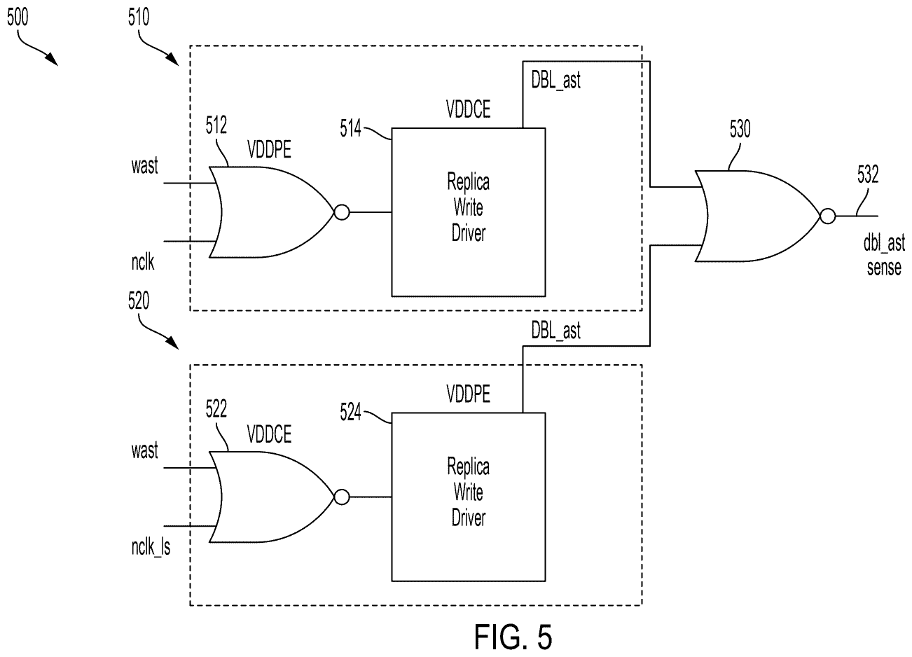

Referring to FIG. 5, a diagram of example replica driver circuitry 500 according to example implementations is illustrated. As depicted, the replica driver circuitry 500 independently evaluates voltage transitions from two separate voltage domains, a first voltage domain (VDDPE) and a second voltage domain (VDDCE). Specifically, the replica driver circuitry 500 comprises two separate replica write driver circuits operating with distinct voltage domain arrangements.

In some aspects, for example, the circuitry 500 includes a first replica write driver circuit 510 and a second replica write driver circuit 520. The first replica write driver circuit 510 includes a first logic gate 512 (e.g., a NOR gate) powered by the first voltage domain (VDDPE) and a first replica driver 514 powered by the second voltage domain (VDDCE). Conversely, the second replica write driver circuit 520 includes a second logic gate 522 (e.g., a NOR gate) powered by the second voltage domain (VDDCE) and a second replica driver 524 powered by the first voltage domain (VDDPE). Both replica circuits 510, 520 receive common inputs, specifically a write assist control signal (WAST) and an internal negated clock signal (e.g., nclk, nclk_ls).

Each of the replica circuits 510, 520 generates a respective dummy bitline assist (DBL_ast) signal based on the received voltage domain signals. An assist enable output signal (dbl_ast_sense) 532 is subsequently generated by logically combining the DBL_ast outputs from the first and second replica write driver circuits 510, 520 using output logic 530 (e.g., a NOR gate). Thus, the assist enable output signal 532 transitions to a high logic state only after both replica circuits 510, 520 have transitioned their respective DBL_ast signals to a low logic state, effectively determining the assist enable output signal 532 based on the later (i.e., slower or worst-case delayed) of the two voltage domain transitions.

Additionally, each of the replica write driver circuits 510, 520 optionally includes respective bleeder devices (not explicitly shown in FIG. 5). These bleeder devices provide controlled delay under specified voltage domain conditions. For example, a bleeder device within the first replica circuit 510 is enabled when the second voltage domain (VDDCE) exceeds the first voltage domain (VDDPE) by a predetermined threshold (e.g., greater than 200 mV). Similarly, the bleeder device within the second replica circuit 520 activates when the first voltage domain (VDDPE) exceeds the second voltage domain (VDDCE) by a predetermined threshold (e.g., greater than 200 mV). These bleeder devices introduce controlled leakage currents to further optimize the timing alignment of the assist signals, ensuring robust operation.

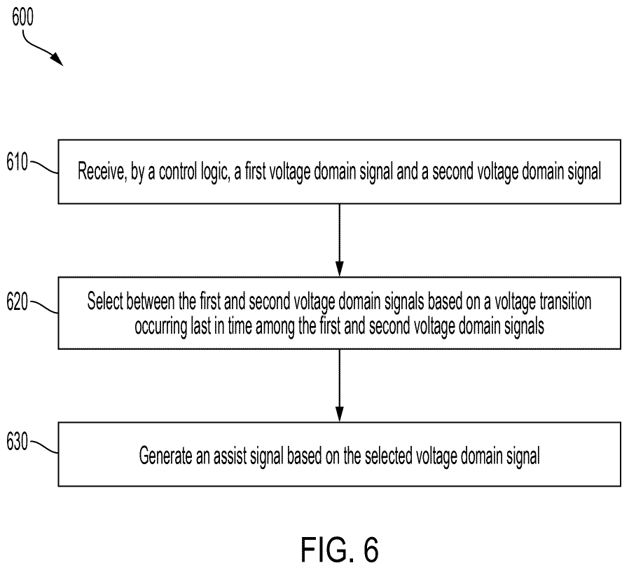

Referring to FIG. 6, a flowchart of an example operational method 600 (i.e., procedure) is shown. Advantageously, the method 600 provides precise timing control of negative bitline assist signals in memory architectures by dynamically evaluating voltage transitions between separate voltage domains. The method 600 may be implemented by the adaptive replica write driver circuitry described above, for example, with reference to FIGS. 1-5. As would be appreciated, each step of the operational method 600 is supported by control logic coupled to a pull-down transistor stack configured within a memory macro control block. By dynamically aligning assist signal timing based on voltage transitions, this method significantly enhances robustness and timing accuracy of memory write operations.

At block 610, the example method 600 includes receiving, by control logic, a first voltage domain signal (e.g., from a first voltage domain, VDDPE) and a second voltage domain signal (e.g., from a second voltage domain, VDDCE) at respective portions of a pull-down transistor stack. For instance, as described with reference to FIGS. 3 and 4, the first and second voltage domain signals (Waen_local and Waen_local_ls, respectively) are each received at corresponding portions of the transistor stack.

At block 620, the example method 600 further includes dynamically selecting between the first and second voltage domain signals based on identifying a voltage transition that occurs last in time among these signals. For example, the method includes selecting the voltage domain signal having the slowest or “worst-case” delayed transition between the two signals, thus ensuring robustness in assist timing.

At block 630, the method 600 includes generating an assist signal based on the selected voltage domain signal. Specifically, as described with reference to FIGS. 3 and 4, the assist signal (e.g., dummy bitline assist, DBL) is generated in response to the identified delayed transition, enabling precise timing alignment for subsequent assist actions.

In certain implementations, the method 600 further includes adjusting a timing of a negative bitline assist signal based on the generated assist signal. For example, the timing-adjusted negative bitline assist signal is subsequently applied, via control circuitry (e.g., through column multiplexers and/or input/output circuitry), to one or more bitcell arrays, ensuring alignment with actual bitline discharge events during memory write operations.

Additionally, in certain implementations, at block 640, the method 600 includes activating adaptive bleeder circuitry coupled to the pull-down transistor stack to provide a controlled delay to the assist signal. Specifically, the bleeder circuitry is activated when a voltage difference between the first and second voltage domain signals exceeds a predetermined threshold (e.g., greater than 200 mV). In such cases, the activated bleeder circuitry introduces a controlled leakage current, thereby precisely extending the delay and ensuring optimal timing robustness for the negative bitline assist signal.

Further, the method 600, in some cases, can include matching capacitive loads associated with the first and second voltage domain signals. Matching these capacitive loads ensures synchronized timing transitions between the two voltage domains, thereby optimizing the overall timing precision and stability of the negative bitline assist signal generation. In certain examples, dynamically selecting the delayed voltage transition between voltage domain signals includes generating an assist signal through a pair of logic gates (e.g., first and second NOR gates). Each of the logic gates is respectively coupled to one of the first and second voltage domains, ensuring that the assist signal reliably follows the voltage transition identified as last in time. This structural configuration significantly enhances timing accuracy and robustness of memory write assist operations.

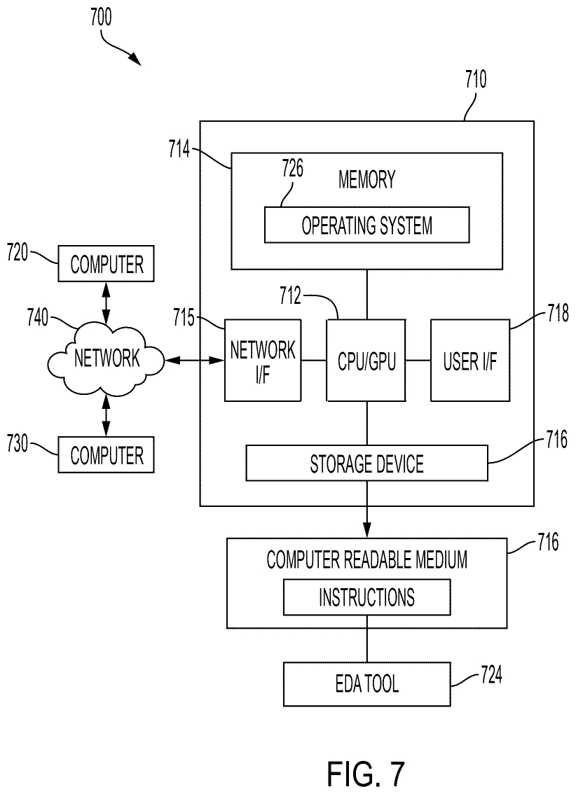

FIG. 7 illustrates example hardware components in a computer system 700 that may be used to facilitate the implementation and optimization of adaptive write assist circuitry as described herein. In certain implementations, the computer system 700 (e.g., a networked computer system and/or server) includes an electronic design automation (EDA) tool 724 configured to execute software instructions corresponding to the procedures described above, for example, with reference to FIGS. 1-6. In particular, the example hardware components depicted in the computer system 700 may be employed to facilitate precise design and verification of adaptive replica write driver circuitry, including control logic, pull-down transistor stacks, load balancing circuitry, and bleeder devices.

Specifically, in the context of the present disclosure, the EDA tool 724 supports synthesis, functional simulation, verification, and timing optimization of adaptive write assist circuits. For instance, the EDA tool 724 can facilitate: (1) automated circuit synthesis, enabling precise structural design of adaptive replica circuitry including transistor sizing and placement; (2) functional simulations under varying voltage domain conditions (e.g., VDDPE and VDDCE domains), ensuring correct timing of negative bitline assist signals; (3) verification of timing alignment and robustness, ensuring assist signals transition accurately in response to worst-case delayed voltage signals; and (4) optimization of capacitive loading and load balancing between different voltage domains, enhancing synchronized timing transitions critical for reliable memory write operations.

In various implementations, the EDA tool 724 is employed to automatically generate and validate circuit layouts and configurations incorporating the described pull-down transistor stacks, dual-domain control logic, bleeder circuitry, and associated adaptive mechanisms as detailed herein. The EDA tool 724 ensures accurate functionality and optimal timing characteristics without requiring extensive manual modifications. Additionally, the EDA tool 724 automates post-layout verification, enabling designers to confirm that adaptive replica write driver circuits perform correctly in both simulation and physical implementation stages.

By leveraging EDA-based automation, advantageously, the described adaptive write assist circuitry can be effectively integrated into complex memory designs, thereby significantly improving memory operation robustness, timing precision, and circuit reliability. This automated approach simplifies design cycles, reduces complexity, and enhances overall yield and performance of semiconductor memory products.

Procedures (e.g., method 600 described with reference to FIG. 6) may be stored as executable program instructions 717 within a computer-readable medium, such as a storage device 716 or memory 714, and executed by computer 710, networked computers 720, 730, or combinations thereof. In various implementations, each of the computers 710, 720, 730 can represent a standalone computing device or be part of a distributed computing environment.

In certain implementations, the system 700 is used with semiconductor integrated circuit (IC) designs, including transistor-level circuits, standard cell-based blocks, or mixed designs containing both custom circuits and standard cells. The system 700 can include databases storing cell libraries, technology files, layout and schematic files, netlists, timing and power analysis information, and physical implementation formats (e.g., OASIS, GDSII, EDIF). These databases may reside within memory 714, storage device 716, or networked storage accessible by computers 710, 720, 730.

The computer 710 includes a central processing unit (CPU) 712 (e.g., optionally including graphics processing units (GPU) or neural processing units (NPU)), coupled to memory 714. Memory 714 may include RAM, cache memory, flash or other programmable memories, and other supplemental memory components. Additionally, the computer 710 is configured to communicate externally through user interface (I/F) 718, incorporating input devices (e.g., keyboards, mouse, touchpads) and output devices (e.g., displays, monitors). Moreover, network interface (I/F) 715 enables communication with external devices or networks 740, facilitating collaborative and distributed computing scenarios.

Computer 710 operates under the management of an operating system 726, stored in memory 714. Operating systems supported by computer 710 may include UNIX®, Linux®, Windows®, AIX®, and others known to those skilled in the art. Operating system 726 provides an execution environment for software applications associated with the described EDA tool 724 and related design automation software programs.

It should be noted that while particular hardware and software elements have been described in relation to FIG. 7, adaptations and modifications can be made within the scope of the described implementations to accommodate specific design and integration requirements. Thus, the provided description is illustrative and not intended to limit the scope of possible implementations of the adaptive write assist circuitry methodologies described herein. In example implementations, circuit-related diagrams have been provided in FIGS. 1-6, whose redundant description has not been duplicated in the related description of analogous circuit-related diagrams. It is expressly incorporated that the same diagrams with identical symbols and/or reference numerals are included in each of the embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, System Verilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the claimed invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the claimed invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for bitline write assist comprising:
a pull-down stack comprising:
a first portion configured to receive a first voltage domain signal; and
a second portion configured to receive a second voltage domain signal different from the first voltage domain signal; and
control logic coupled to the pull-down stack, wherein the control logic is configured to select between the first and second voltage domain signals based on a voltage transition occurring last in time among the first and second voltage domain signals.

2. The circuit of claim 1, wherein:
the circuit is configured to generate an assist signal that induces generation of a negative bitline assist signal based on the selected voltage domain signal.

3. The circuit of claim 1, further comprising:
bleeder circuitry coupled to the pull-down stack, wherein the bleeder circuitry is configured to delay the negative bitline assist signal in response to a voltage difference between the first and second voltage domain signals exceeding a predetermined threshold.

4. The circuit of claim 3, wherein the bleeder circuitry comprises a transistor having a gate terminal configured to receive one of the first or second voltage domain signals.

5. The circuit of claim 4, wherein the transistor is configured to provide a leakage current.

6. The circuit of claim 1, wherein the first portion of the pull-down stack comprises:
first and second transistors, wherein:
gates of the first and second transistors are configured to receive the first voltage domain signal.

7. The circuit of claim 1, wherein the second portion of the pull-down stack comprises:
third and fourth transistors, wherein:
gates of the third and fourth transistors are configured to receive the second voltage domain signal.

8. The circuit of claim 1, wherein the first and second transistor portions are configured to selectively control timing of a negative bitline assist signal based on a comparison of voltage transitions of the first and second voltage domain signals.

9. The circuit of claim 1, further comprising:
load balancing circuitry configured to match timing transitions of the first and second voltage domain signals.

10. The circuit of claim 9, wherein the matching timing transitions comprise: balancing capacitive loads from respective first and second voltage domains.

11. The circuit of claim 1, wherein:
the control logic comprises first and second logic gates powered by respective first and second voltage domains.

12. The circuit of claim 1, further comprising:
a memory array with bitcells;
a control block configured to provide a negative bitline assist signal during write operations; and
the circuit for bitline write assist as claimed in claim 1 within the control block, wherein:
the circuit receives inputs from two separate voltage domains, selects a last-in-time voltage transition between voltage domain signals of the voltage domains, and adjusts a timing of the negative bitline assist signal in response to voltage fluctuations.

13. The circuit of claim 12, further comprising:
bleeder circuitry coupled to the circuit, wherein:
the bleeder circuitry is configured to provide a leakage current to delay the negative bitline assist signal when a voltage difference between the first and second voltage domains exceeds a predetermined threshold.

14. A method for bitline write assist comprising:
receiving, by a control logic, a first voltage domain signal and a second voltage domain signal;
selecting between the first and second voltage domain signals based on a voltage transition occurring last in time among the first and second voltage domain signals; and
generating an assist signal based on the selected voltage domain signal.

15. The method of claim 14, further comprising:
adjusting a timing of a negative bitline assist signal based on the generated assist signal; and
applying, from control circuitry to one or more bitcell arrays, the timing-adjusted negative bitline assist signal for memory write operation.

16. The method of claim 14, further comprising:
activating bleeder circuitry to provide a delay to the assist signal when a voltage difference between the first and second voltage domain signals exceeds a predetermined threshold.

17. The method of claim 16, wherein the bleeder circuitry is configured to provide a leakage current when the voltage difference exceeds the predetermined threshold.

18. The method of claim 14, further comprising:
matching capacitive loads of the first and second voltage domain signals, wherein the matched capacitive loads corresponds synchronized signal transitions.

19. The method of claim 14, wherein selecting the voltage transition comprises:
generating, by a pair of logic gates, an assist signal based on the last in time voltage transition, wherein:
each of the pair of logic gates is respectively coupled to respective first and second voltage domains.

20. A circuit for bitline write assist comprising:
a first replica write driver circuit powered by a first voltage domain and comprising a first logic gate powered by the first voltage domain and a first replica driver powered by a second voltage domain different from the first voltage domain;
a second replica write driver circuit powered by the second voltage domain and comprising a second logic gate powered by the second voltage domain and a second replica driver powered by the first voltage domain;
wherein each of the first and second replica write driver circuits generates a respective assist signal; and
output logic configured to receive the respective assist signals from the first and second replica write driver circuits and generate an assist enable output signal based on a voltage transition occurring last in time among voltage transitions from the first and second voltage domains.
